(19) United States
(12) Patent Application Publication
(10) Pub. No.: US 2006/0290386 A1
(43) Pub. Date: Dec. 28, 2006

(54) NAND gate, a NOR gate, and output buffer and method thereof

(75) Inventors: Woo-jin Lee, Seongnam-si (KR); Sung-hoon Kim, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/430,111

(22) Filed: May 9, 2006

(30) Foreign Application Priority Data
Jun. 23, 2005 (KR) 10-2005-0054363

(51) Int. Cl. H03K 19/094

(52) U.S. Cl. 326/122

(57) ABSTRACT

A NAND gate, a NOR gate, an output buffer and method thereof. An example embodiment of the present invention is directed to a NAND gate, including a first transistor having a source to which a supply voltage is applied and a gate to which a ground voltage is applied, a first plurality of transistors connected in series between the first transistor and the ground voltage, gates of the first plurality of transistors receiving a first input signal, the first plurality of transistors including at least three transistors and a second plurality of transistors connected in series between the first transistor and the ground voltage, the second plurality of transistors not in series with the first plurality of transistors and including at least three transistors. Another example embodiment of the present invention is directed to a NOR gate including a first plurality of transistors connected in series with a supply voltage, the first plurality of transistors including first, second and third transistors, a second plurality of transistors connected in series with the supply voltage and not connected in series with the first plurality of transistors, the second plurality of transistors including fourth, fifth and sixth transistors and a seventh transistor connected between the third and sixth transistors and a ground voltage and having a gate connected to the supply voltage. The example NOR and NAND gates may be employed within the example output buffer. The example NOR and NAND gates may also be employed in the example method so as to reduce skew by attaining the same output characteristics.

### PRIORITY STATEMENT

This application claims the benefit of priority under 35 USC § 119 from Korean Patent Application No. 10-2005-0054363, filed on Jun. 23, 2005, in the Korean Intellectual Property Office, the contents of which is incorporated herein by reference in its entirety.

### BACKGROUND OF THE INVENTION

1. Field of the Invention

Example embodiments of the present invention relate generally to a NAND gate, a NOR gate, an output buffer and method thereof, and more particularly to a NAND gate, a NOR gate, an output buffer and method of reducing skew.

2. Description of the Related Art

Output pins of a semiconductor device may be internally connected to output buffers for driving external loads connected to the output pins. A tri-state output buffer may include a NAND gate or a NOR gate for maintaining a tri-state if no input signal is received. The tri-state output buffer may control data output to an external bus.

FIG. 1 is a circuit diagram of a conventional output buffer 100. Referring to FIG. 1, the output buffer 100 may include a NAND gate 102 that receives first and second input signals D1 and D2 and a NOR gate 104 that receives third and fourth input signals D3 and D4. The output of the NAND gate 102 may be connected to a gate of a pull-up transistor 106. The output of the NOR gate 104 may be connected to a gate of a pull-down transistor 108. Respective drains of the pull-up transistor 106 and the pull-down transistor 108 may be connected to the same node and may collectively generate an output signal DQ of the output buffer 100.

Referring to FIG. 1, each of the first through fourth input signals D1 through D4 of the output buffer 100 may have the same output characteristics under certain conditions. For example, if it is assumed that the first and third input signals D1 and D3 have the same phase when the first and third input signals D1 and D3 transition to a first logic level (e.g., a higher logic level), the output buffer 100 may generate an output signal DQ through the NAND gate 102. Likewise, when the first and third input signals D1 and D3 transition to a second logic level (e.g., a lower logic level), the output buffer 100 may generate an output signal DQ through the NOR gate 104.

FIG. 2A is a circuit diagram of the NAND gate 102 of FIG. 1. Referring to FIG. 2A, the NAND gate 102 may include first and second PMOS transistors P0 and P1 connected in parallel and first and second NMOS transistors N0 and N1 connected in series. Sources of the first and second PMOS transistors P0 and P1 may be connected to a supply voltage VDD. Drains of the first and second PMOS transistors P0 and P1 may be connected to a drain of the second NMOS transistor N1. A source of the first NMOS transistor N0 may be connected to a ground voltage VSS. A first input terminal A may be connected to the gates of the first PMOS transistor P0 and the second NMOS transistor N1. A second input terminal B may be connected to the gates of the second PMOS transistor P1 and the first NMOS transistor N0. The drains of the first and second PMOS transistors P0 and P1 and the drain of the second NMOS transistor N1 may each be connected to an output terminal Z of the NAND gate 102.

FIG. 2B is a circuit diagram of the NOR gate 104 of FIG. 1. Referring to FIG. 2B, the NOR gate 104 may include third and fourth PMOS transistors P2 and P3 connected in series and third and fourth NMOS transistors N2 and N3 connected in parallel. A source of the fourth PMOS transistor P3 may be connected to a supply voltage VDD. Drains of the third and fourth NMOS transistors N2 and N3 may be connected to a ground voltage VSS. A first input terminal A may be connected to the gates of the third PMOS transistor P2 and the third NMOS transistor N2. A second input terminal B may be connected to the gates of the fourth PMOS transistor P3 and the fourth NMOS transistor N3. The drain of the third PMOS transistor P2 and the drains of the third and fourth NMOS transistors N2 and N3 may be connected to an output terminal Z of the NOR gate 104.

Returning to the NAND gate 102 illustrated in FIG. 2A, the channel width 2W of the first and second NMOS transistors N0 and N1 may be greater than the channel width W of the first and second PMOS transistors P0 and P1. Also, referring to the NOR gate 104 of FIG. 2B, the channel width 2W of the third and fourth PMOS transistors P2 and P3 may be greater than the channel width W of the third and fourth NMOS transistors N2 and N3. If the above channel width conditions are met, a single PMOS transistor (e.g., P0 or P1) having the channel width W may be positioned on a path from the supply voltage VDD to the output terminal Z. Concurrently, referring to FIG. 2B in the NOR gate 104, two PMOS transistors P3 and P2 having the channel width 2W may be positioned on a path from the supply voltage VDD to the output terminal Z.

Accordingly, the number of transistors on the path from the supply voltage VDD to the output terminal Z in the NAND gate 102 of FIG. 2A may be different from the number of transistors on the path from the supply voltage VDD to the output terminal Z in the NOR gate 104 of FIG. 2B. Also, because of differences in the channel widths of the transistors P0 through P3 and N0 through N3, the input capacitance of the first input terminal A of the NAND gate 102 may be different from the input capacitance of the first input terminal A of the NOR gate 104.

FIG. 3A illustrates a circuit diagram of another conventional NAND gate 310. Referring to FIG. 3A, the NAND gate 310 may include two PMOS transistors (e.g., two of P31, P30 and P32) having channel widths 2W, which may be disposed on a path from a supply voltage VDD to an output terminal Z. The NAND gate 310 may further include two NMOS transistors (e.g., two of N31, N30 and N32) having channel widths 2W, which may be disposed on a path from a ground voltage VSS to the output terminal Z.

FIG. 3B illustrates a circuit diagram of another conventional NOR gate 320. Referring to FIG. 3B, the NOR gate 320 may include two PMOS transistors (e.g., two of P34, P33 and P35) having channel widths 2W which may be disposed on a path from a supply voltage VDD to an output terminal Z. The NOR gate 320 may further include two NMOS transistors (e.g., two of N34, N33 and N35) also having channel widths 2W, which may be disposed on a path from a ground voltage VSS and the output terminal Z.

Accordingly, the number of transistors on the path from the supply voltage VDD to the output terminal Z in the NAND gate 310 may be the same as the number of transistors on the path from the supply voltage VDD to the output terminal Z in the NOR gate 320.

However, with respect to paths from the first input terminal A and/or the second input terminal B, the load of the NAND gate 310 and the NOR gate 320 may be mismatched. For example, in the NAND gate 310 and/or the NOR gate 320, the load from the output terminal Z to the input terminal A when the logic level of the second input terminal B varies (e.g., transitions) while the first input terminal A is stable at a given logic level (e.g., one of the first and second logic levels) may be different as compared to the load from the output terminal Z to the input terminal A when the logic level of the first input terminal A varies (e.g., transitions) while the second input terminal B is stable at a given logic level (e.g., one of the first and second logic levels). In an example, the above-described mismatched load phenomenon may occur because the location of the first input terminal A is different from that of the second input terminal B.

Accordingly, because the load of the NAND gate 310 may be the same as the load of the NOR gate 320 from the supply voltage to the output terminals Z, but may be different from the load of the NOR gate 320 from the output terminals Z to the first and second input terminals A and B, data skew may occur in the output terminals Z when similar signals (e.g., identical signals) are received through the first and second input terminals A and B. Furthermore, if the NAND gate 310 and the NOR gate 320 are used in an output buffer, output data skew DQ may occur.

### SUMMARY OF THE INVENTION

An example embodiment of the present invention is directed to a NAND gate, including a first transistor having a source to which a supply voltage is applied and a gate to which a ground voltage is applied, a first plurality of transistors connected in series between the first transistor and the ground voltage, gates of the first plurality of transistors receiving a first input signal, the first plurality of transistors including at least three transistors and a second plurality of transistors connected in series between the first transistor and the ground voltage, the second plurality of transistors not in series with the first plurality of transistors and including at least three transistors.

Another example embodiment of the present invention is directed to a NOR gate including a first plurality of transistors connected in series with a supply voltage, the first plurality of transistors including first, second and third transistors, a second plurality of transistors connected in series with the supply voltage and not connected in series with the first plurality of transistors, the second plurality of transistors including fourth, fifth and sixth transistors and a seventh transistor connected between the third and sixth transistors and a ground voltage and having a gate connected to the supply voltage.

Another example embodiment of the present invention is directed to an output buffer including a NAND gate receiving a first input signal and a second input signal and outputting a NAND output signal, and a NOR gate receiving a third input signal and a fourth input signal and outputting a NOR output signal, the NAND and NOR gates configured so as to have the substantially the same output characteristics.

Another example embodiment of the present invention is directed to a method of skew reduction, including arranging a NAND gate and a NOR gate such that output characteristics of each of the NAND gate and the NOR gate are substantially the same irrespective of voltage fluctuations at first and second input terminals of the NAND and NOR gates, respectively.

Another example embodiment of the present invention is directed to a NAND gate and a NOR gate having the same capacitance.

Another example embodiment of the present invention is directed to an output buffer including a NAND gate and a NOR gate with the same capacitance.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a circuit diagram of a conventional output buffer.

FIG. 2A is a circuit diagram of a conventional NAND gate.

FIG. 2B is a circuit diagram of a conventional NOR gate.

FIG. 3A is a circuit diagram of another conventional NAND gate.

FIG. 3B is a circuit diagram of another conventional NOR gate.

FIG. 4A is a circuit diagram of a NAND gate according to an example embodiment of the present invention.

FIG. 4B is a circuit diagram of a NOR gate according to an example embodiment of the present invention.

FIG. 5 illustrates an output buffer according to another example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

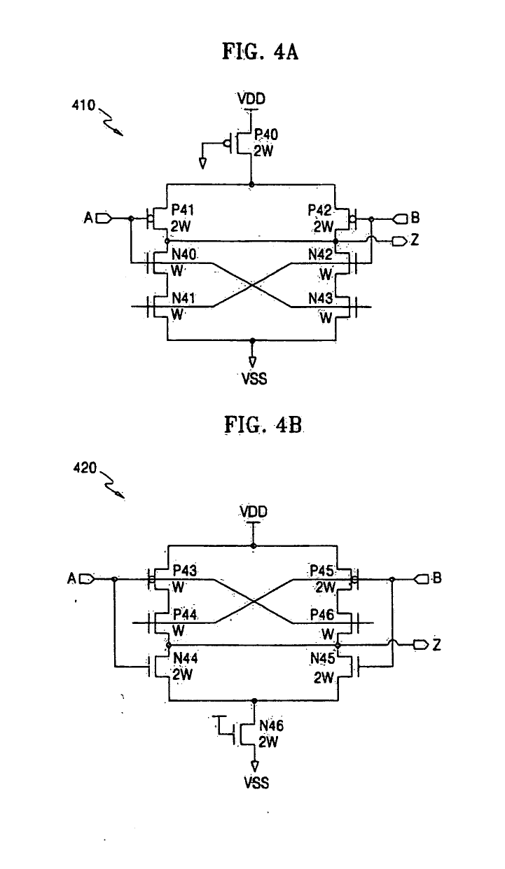

FIG. 4A is a circuit diagram of a NAND gate 410 according to an example embodiment of the present invention.

In the example embodiment of FIG. 4A, the NAND gate 410 may include a first PMOS transistor P40 with a source connected to a supply voltage VDD and a gate connected to a ground voltage VSS. The NAND gate 410 may further include a second PMOS transistor P41 and first and second NMOS transistors N40 and N41 which may be connected in series between the drain of the first PMOS transistor P40 and the ground voltage VSS. The NAND gate 410 may further include a third PMOS transistor P42 and third and fourth NMOS transistors N42 and N43 which may be connected in series between the drain of the first PMOS transistor P40 and the ground voltage VSS (e.g., not in series with the transistors P41, N40 and N41).

In the example embodiment of FIG. 4A, the gates of the second PMOS transistor P41, the first NMOS transistor N40, and the fourth NMOS transistor N43 may be connected to a first input terminal A. The gates of the third PMOS transistor P42, the third NMOS transistor N42, and the second NMOS transistor N41 may be connected to a second input terminal B. The drains of the second and third PMOS transistors P41 and P42 and the drains of the first and third NMOS transistors N40 and N42 may be connected in common to an output terminal Z.

In an example, referring to FIG. 4A, a channel width of each of the PMOS transistors P40, P41, and P42 may be set to a first channel width (e.g., 2W), and a channel width of each of the NMOS transistors N40, N41, N42 and N43 may be set to a second channel width (e.g., W). The NAND gate 410 may include two transistors (e.g., P40/P41, P40/P42, etc.) on a path from the supply voltage VDD to the output terminal Z. The NAND gate 410 may also include two transistors (e.g., N40/N41, N42/N43, etc.) on a path from the ground voltage VSS to the output terminal Z.

In another example, on a path from the first input terminal A, the PMOS transistor P41 may have the first channel width (e.g., 2W) and the NMOS transistors N40 and N43 may each have the second channel width (e.g., W). On a path from the second input terminal B, the PMOS transistor P42 may have the first channel width (e.g., 2W) and the NMOS transistors N41 and N42 may each have the second channel width (e.g., W).

FIG. 4B is a circuit diagram of a NOR gate 420 according to another example embodiment of the present invention.

In the example embodiment of FIG. 4B, the NOR gate 420 may include first and second PMOS transistors P43 and P44 and a first NMOS transistor N44 which may be connected in series with a supply voltage VDD. The NOR gate 420 may further include third and fourth PMOS transistors P45 and P46 and a second NMOS transistor N45 which may be connected in series with the supply voltage VDD. The NOR gate 420 may further include a third NMOS transistor N46 which may be connected between the sources of the first NMOS transistor N44 and the second NMOS transistor N45 and the ground voltage VSS. The third NMOS transistor N46 may have a gate connected to the supply voltage VDD.

In the example embodiment of FIG. 4B, the gates of the first and fourth PMOS transistors P43 and P46 and the first NMOS transistor N44 may be connected to a first input terminal A, and the gates of the second and third PMOS transistors P44 and P45 and the second NMOS transistor N45 may be connected to a second input signal B. The drains of the second and fourth PMOS transistors P44 and P46 and the drains of the first and second NMOS transistors N44 and N45 may be connected in common to an output terminal Z.

In an example, referring to FIG. 4B, the channel width of each of the PMOS transistors P43, P44, P45 and P46 may be set to the second channel width (e.g., W) and the channel width of each of the NMOS transistors N44, N45 and N46 may be set to the first channel width (e.g., 2W).

In another example, referring to FIG. 4B, the NOR gate 420 may include two transistors (e.g., P43/P44, P45/P46, etc.) on a path from the supply voltage VDD to the output terminal Z. The NOR gate 420 may further include two transistors (e.g., N44/N46, N45/N46, etc.) on a path from the ground voltage VSS to the output terminal Z. On a path from the first input signal A, the NOR gate 420 may include two PMOS transistors P43 and P46 with the second channel width (e.g., W) and a NMOS transistor N44 having the first channel width (e.g., 2W).

In the example embodiment of FIGS. 4A and 4B, the number of transistors on the path from the supply voltage VDD and/or the ground voltage VSS to the output terminal Z in the NAND gate 410 may equal the number of transistors on the path from the supply voltage VDD and/or the ground voltage VSS to the output terminal Z in the NOR gate 420. Further, the channel widths and number of transistors connected to the first input terminal A may be the same as the channel widths and number of transistors connected to the second input terminal B. That is, in the NAND gate 410 and the NOR gate 420, a voltage supply path load from the first input terminal A to the output terminal Z may equal a voltage supply path load from the second input terminal B to the output terminal Z.

The NAND gate 410 and NOR gate 420, paired together in accordance with another example embodiment of the present invention, may operate in a uniform manner with respect to changes in signals received through the first and second terminals A and B, respectively. Thereby, output characteristics the NAND gate 410 and the NOR gate 420 may be synchronized/aligned.

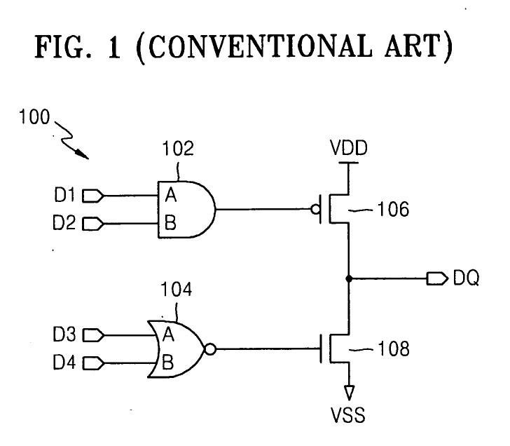

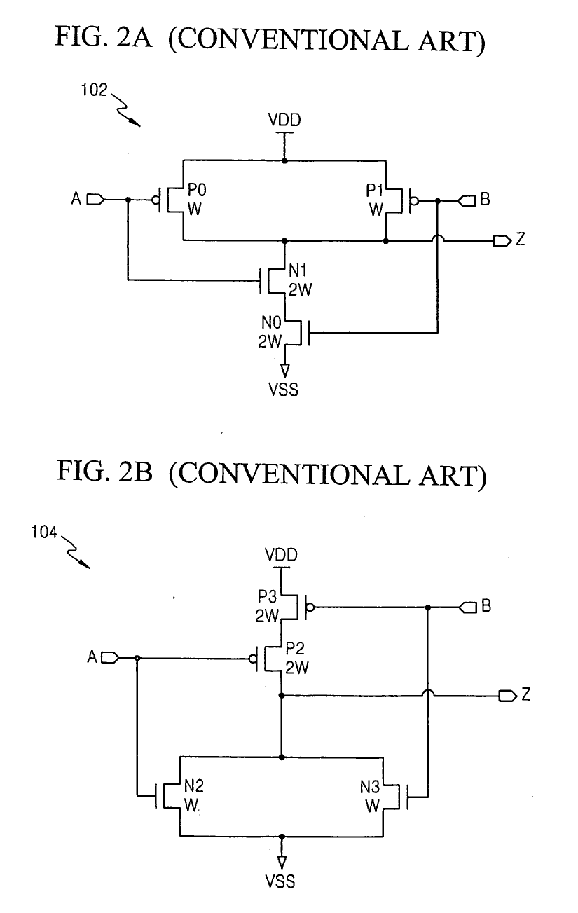

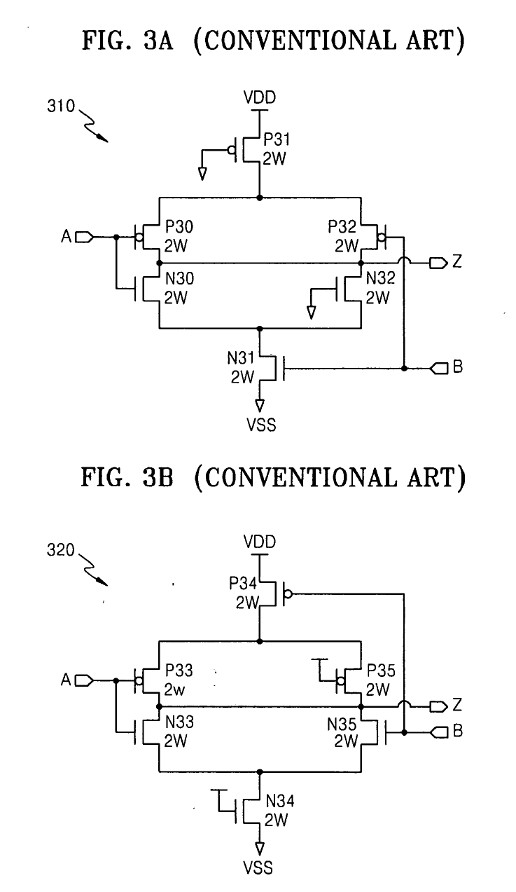

In another example embodiment of the present invention, the paired NAND gate 410 and NOR gate 420 may be proportionately (e.g., equally) influenced by changes in a semiconductor manufacturing process, a supply voltage, a temperature, etc., so as to attain proportional (e.g., identical) output characteristics. In an example, if the paired NAND gate 410 and NOR gate 420 are used in the output buffer 100 illustrated in FIG. 1, a level of skew of an output signal DQ may be reduced as compared to the output buffer 100 employing conventional NAND/NOR gates.

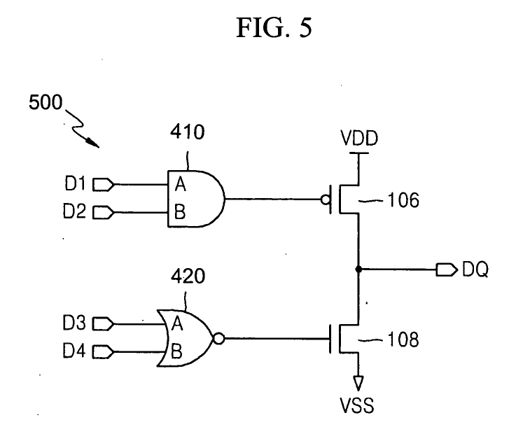

FIG. 5 illustrates an output buffer 500 according to another example embodiment of the present invention. In the example embodiment of FIG. 5, the output buffer 500 may be similar to the conventional output buffer 100 of FIG. 1. For example, both the output buffers 100 and 500 may include the pull-up transistor 106 and the pull-down transistor 108. However, the output butter 500 of FIG. 5 may include the NAND gate 410 in place of the conventional NAND gate 102 and the NOR gate 420 in place of the conventional NOR gate 420. The output buffer 500 may be associated with aligned or symmetrical output characteristics due at least in part to an evenly distributed voltage load paths from input ports to output ports at each of the NAND gate 410 and the NOR gate 420.

Example embodiments of the present invention being thus described, it will be obvious that the same may be varied in many ways. For example, it is understood that the above-described first and second logic levels may correspond to a higher level and a lower logic level, respectively, in an example embodiment of the present invention. Alternatively, the first and second logic levels/states may correspond to the lower logic level and the higher logic level, respectively, in other example embodiments of the present invention.

Such variations are not to be regarded as a departure from the spirit and scope of example embodiments of the present invention, and all such modifications as would be obvious to one skilled in the art are intended to be included within the scope of the following claims.

What is claimed is:

1. A NAND gate comprising:
a first transistor having a source to which a supply voltage is applied and a gate to which a ground voltage is applied;
a first plurality of transistors connected in series between the first transistor and the ground voltage, gates of the first plurality of transistors receiving a first input signal, the first plurality of transistors including at least three transistors; and
a second plurality of transistors connected in series between the first transistor and the ground voltage, the second plurality of transistors not in series with the first plurality of transistors and including at least three transistors.

2. The NAND gate of claim 1, wherein the first plurality of transistors includes second, third and fourth transistors and the second plurality of transistors includes fifth, sixth and seventh transistors.

3. The NAND gate of claim 2, wherein a first input signal is applied to gates of the second, third and seventh transistors, a second input signal is applied to gates of the fourth, fifth and sixth transistors, and drains of the second and third transistors and drains of the fifth and sixth transistors are connected in common to an output terminal outputting an output signal.

4. The NAND gate of claim 2, wherein the first, second and fifth transistors are PMOS transistors, and the third, fourth, sixth and seventh transistors are NMOS transistors.

5. The NAND gate of claim 4, wherein a channel width of each of the PMOS transistors is set to a first channel width each of the NMOS transistors is set to a second channel width.

6. The NAND gate of claim 5, wherein the first channel width is greater than the second channel width.

7. A NOR gate comprising:
a first plurality of transistors connected in series with a supply voltage, the first plurality of transistors including first, second and third transistors;
a second plurality of transistors connected in series with the supply voltage and not connected in series with the first plurality of transistors, the second plurality of transistors including fourth, fifth and sixth transistors; and
a seventh transistor connected between the third and sixth transistors and a ground voltage and having a gate connected to the supply voltage.

8. The NOR gate of claim 7, wherein a first input signal is applied to gates of the first, third and fifth transistors, a second input signal is applied to gates of the second, fourth, and sixth transistors, and drains of the second and third transistors and drains of the fifth and sixth transistors are connected in common to an output terminal outputting an output signal.

9. The NOR gate of claim 7, wherein the first, second, fourth and fifth transistors are PMOS transistors, and the third, sixth and seventh transistors are NMOS transistors.

10. The NOR gate of claim 9, wherein the NMOS transistors have a first channel width and the PMOS transistors have a second channel width.

11. The NOR gate of claim 10, wherein the first channel width is greater than the second channel width.

12. An output buffer comprising:
a NAND gate receiving a first input signal and a second input signal and outputting a NAND output signal; and
a NOR gate receiving a third input signal and a fourth input signal and outputting a NOR output signal, the NAND and NOR gates configured so as to have the substantially the same output characteristics irrespective of voltage fluctuations at first and second input terminals of the NAND and NOR gates, respectively.

13. The output buffer of claim 12, wherein the output characteristics of the NAND gate and the NOR gate respond in substantially the same fashion to variations in semiconductor manufacturing processes, supply voltage levels and temperatures.

14. The output buffer of claim 12, wherein NAND gate is the NAND gate of claim 1.

15. The output buffer of claim 12, wherein the NOR gate is the NOR gate of claim 7.

16. A method of skew reduction, comprising:
arranging a NAND gate and a NOR gate such that output characteristics of each of the NAND gate and the NOR gate are substantially the same irrespective of voltage fluctuations at first and second input terminals of the NAND and NOR gates, respectively.

17. The method of claim 16, wherein a first voltage load along a first path from the first input terminal and a first output terminal of the NAND gate substantially equals a second voltage load along a second path from the second input terminal to a second output terminal of the NOR gate.

18. The method of claim 16, wherein the NAND gate includes:
a first transistor having a source to which a supply voltage is applied and a gate to which a ground voltage is applied;
a first plurality of transistors connected in series between the first transistor and the ground voltage, gates of the first plurality of transistors receiving a first input signal, the first plurality of transistors including at least three transistors; and
a second plurality of transistors connected in series between the first transistor and the ground voltage, the second plurality of transistors not in series with the first plurality of transistors and including at least three transistors.

19. The method of claim 16, wherein the NOR gate includes:
a first plurality of transistors connected in series with a supply voltage, the first plurality of transistors including first, second and third transistors;
a second plurality of transistors connected in series with the supply voltage and not contacted in series with the first plurality of transistors, the second plurality of transistors including fourth, fifth and sixth transistors; and
a seventh transistor connected between the third and sixth transistors and a ground voltage and having a gate connected to the supply voltage.

20. An output buffer performing the method of claim 16.
